(19) United States
(12) Patent Application Publication
(10) Pub. No.: US 2025/0260186 A1
(43) Pub. Date: Aug. 14, 2025

(54) SHORTING BAR, MOUNTING STRUCTURE, AND UNIT

(71) Applicant: FANUC CORPORATION, Yamanashi (JP)

(72) Inventors: Kouyou Iwasaki, Yamanashi (JP); Jianzhou Chen, Yamanashi (JP); Takaki Ishii, Yamanashi (JP)

(21) Appl. No.: 19/195,113

(22) Filed: Apr. 30, 2025

Related U.S. Application Data
(63) Continuation of application No. PCT/JP2023/012940, filed on Mar. 29, 2023.

(51) Int. Cl. H01R 12/70; H01R 12/71; H01R 13/10

(52) U.S. Cl. CPC H01R 12/7076; H01R 12/707; H01R 12/7082; H01R 12/716; H01R 13/10

(57) ABSTRACT

A shorting bar electrically connected to a lead component including an engaging portion that is to be engaged with the lead of the lead component. The engaging portion may be a socket for receiving the lead of the lead component.

### CROSS-REFERENCE TO RELATED APPLICATIONS

This application is a bypass continuation application of International Application No. PCT/JP2023/012940 filed Mar. 29, 2023.

### BACKGROUND

### Field

The present disclosure relates to a short bar, a mounting structure, and a unit.

### Discussion of the Related Art

Printed circuit boards are made by etching copper foil. Since there is an upper limit to the thickness of copper foil, printed circuit boards are not suitable for use with large currents, but are suitable for use with small currents.

When it is necessary to pass a large current through a printed circuit board, a short bar composed of a conductor is used (Japanese Unexamined Patent Publication (Kokai) Nos. 63-271996 and 04-345082).

However, when a large current is passed from a short bar to a lead part via a printed circuit board, there is a problem in that the lead part and the short bar generate a large amount of heat.

Furthermore, when the pattern of a printed circuit board is enlarged, there is a problem in that the size of the printed circuit board increases, and when the thickness of the copper foil of a printed circuit board is increased, there is a problem in that production cost increases.

As a result, the suppression of heat generation when a large current flows, the prevention of an increase in size of the overall structure, and a reduction in production costs are desired.

### SUMMARY

According to a first aspect of the present disclosure, there is provided a short bar for electrical connection to a lead part, comprising an engagement part which is to be engaged with a lead of the lead part.

The objects, features, and advantages of the present disclosure will become more apparent from the following description of the embodiments in conjunction with the accompanying drawings.

### BRIEF DESCRIPTION OF DRAWINGS

FIG. 1 is a perspective view of a mounting structure comprising a short bar according to a first embodiment.

FIG. 2 is a perspective view of a mounting structure comprising a short bar according to the prior art.

FIG. 3A is a perspective view of the short bar, etc., based on the first embodiment.

FIG. 3B is a bottom view of FIG. 3A.

FIG. 4 is a perspective view of a short bar based on a second embodiment.

FIG. 5A is a view showing a first modification example of the short bar shown in FIG. 4.

FIG. 5B is a view showing a second modification example of the short bar shown in FIG. 4.

FIG. 5C is a view showing a third modification example of the short bar shown in FIG. 4.

FIG. 6A is a view showing a first modification example of the socket shown in FIG. 4.

FIG. 6B is a view showing a second modification example of the socket shown in FIG. 4.

FIG. 7A is a view showing a fourth modification example of the short bar shown in FIG. 4.

FIG. 7B is a view showing a fifth modification example of the short bar shown in FIG. 4.

FIG. 7C is a view showing a sixth modification example of the short bar shown in FIG. 4.

FIG. 8A is a first perspective view showing a mounting structure according to a third embodiment.

FIG. 8B is a second perspective view showing the mounting structure shown in FIG. 8A.

FIG. 8C is a side view of FIG. 8B.

FIG. 9A is a first perspective view of a unit according to a fourth embodiment.

FIG. 9B is a second perspective view of the unit according to the fourth embodiment.

FIG. 10A is an exploded view of a unit according to a fifth embodiment.

FIG. 10B is a perspective view of a unit according to the fifth embodiment.

FIG. 11A is a first perspective view of a unit according to a sixth embodiment.

FIG. 11B is a second perspective view of the unit according to the sixth embodiment.

FIG. 12A is a first perspective view of a unit according to a seventh embodiment.

FIG. 12B is a second perspective view of the unit according to the seventh embodiment.

FIG. 12C is a third perspective view of the unit according to the seventh embodiment.

FIG. 12D is a fourth perspective view of the unit according to the seventh embodiment.

### DETAILED DESCRIPTION OF THE EMBODIMENTS

The embodiments of the present disclosure will be described below with reference to the attached drawings. In the drawings, corresponding constituent elements have been assigned common reference signs.

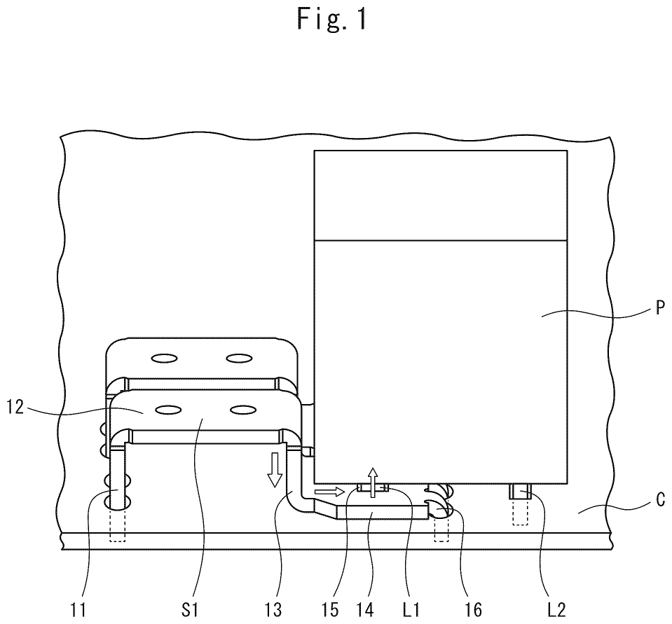

FIG. 1 is a perspective view of a mounting structure comprising a short bar based on a first embodiment. In FIG. 1, at least one short bar S1 and a part P are mounted on the surface of a printed circuit board C. The part P may be a lead part comprising at least two leads L1, L2.

The short bar S1 is an integral member composed of a conductor, for example, a conductive metal. The short bar S1 primarily comprises two rising parts 11, 13 rising from the surface of the printed circuit board C, a first extension part 12 connecting the rising parts 11, 13 at a position spaced apart from the surface of the printed circuit board C, and a second extension part 14 extending from the rising part 13 along the surface of the printed circuit board C. As can be understood from the drawing, the base part of the rising part 11 and the end part 16 of the second extension part 14 extend to the back side through the corresponding through holes of the printed circuit board C.

The configuration of the short bar S1 is not limited to that shown in FIG. 1, and it is sufficient that the short bar S1 comprise at least the portions corresponding to the rising part 11 and the second extension part 14.

The second extension part 14 includes an engagement part 15 for engagement with the lead L1 of the part P. The engagement part 15 shown in FIG. 1 can be a through hole formed in the second extension part 14. The engagement part 15 preferably has dimensions sufficient for mating of the lead L1.

Thus, when a current is passed through the short bar S1 from the rising part 11 side, the current passes through the first extension part 12, the rising part 13, and the second extension part 14, and is transmitted to the lead L1 via the engagement part 15. Since the current does not pass through a circuit pattern (not illustrated) on the back side of the printed circuit board C at this time, heat generation in the printed circuit board C can be suppressed. The resistance value of the short bar S1 is lower than the resistance value of the circuit pattern (not illustrated) of the printed circuit board C. Thus, even when a relatively large current is passed through the short bar S1, heat generation in the short bar S1 can be relatively small. The same is true for the part P.

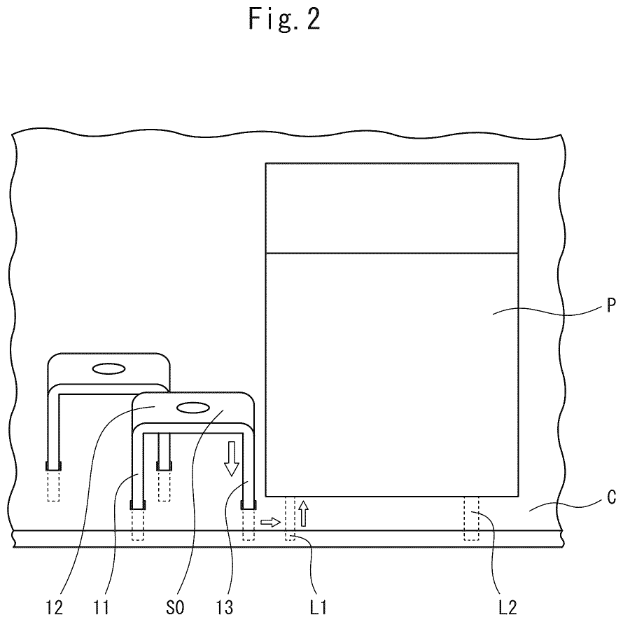

FIG. 2 is a perspective view of a mounting structure comprising a short bar based on the prior art. The short bar S0 of the prior art shown in FIG. 2 comprises two rising parts 11, 13 similar to those described above, and a first extension part 12. The base parts of the rising parts 11, 13 extend to the back side of the printed circuit board C as described above. In other words, the short bar S0 of the prior art does not comprise a second extension part 14 including an engagement part 15.

When a current is passed through the short bar S0 from the rising part 11 side, the current passes through the first extension part 12 and the rising part 13, and is transmitted to the lead L1 via a circuit pattern (not illustrated) of the printed circuit board C. Specifically, in the prior art, the current passes through the circuit pattern (not illustrated) of the printed circuit board C, and as a result, the printed circuit board C heats up. In particular, when the current is relatively large, the heat generated by the printed circuit board C also increases accordingly. The same is true for the short bar S0 and the part P.

Thus, in the prior art, it was necessary to form a wide pattern or to make the copper foil used to form the pattern thicker in order to suppress heat generation on the printed circuit board C. In the case of forming a wide pattern, there was a problem in that the printed circuit board C would become larger, and in the case of making the copper foil thicker, there was a problem in that the production cost would increase.

In the first embodiment shown in FIG. 1, a large current can be transmitted from the rising part 11 of the short bar S1 to the part P without passing through the circuit pattern of the printed circuit board C. Thus, it is possible to prevent the circuit pattern of the printed circuit board C itself from heating up, and thus, the problems described above can be avoided.

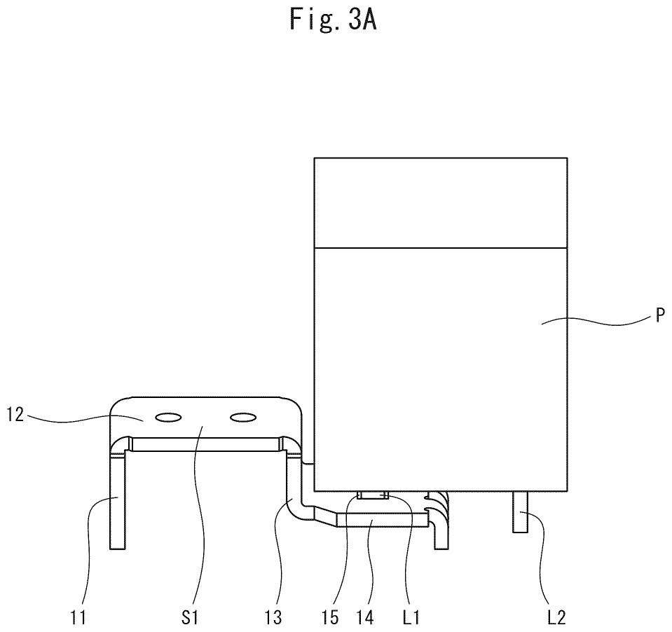

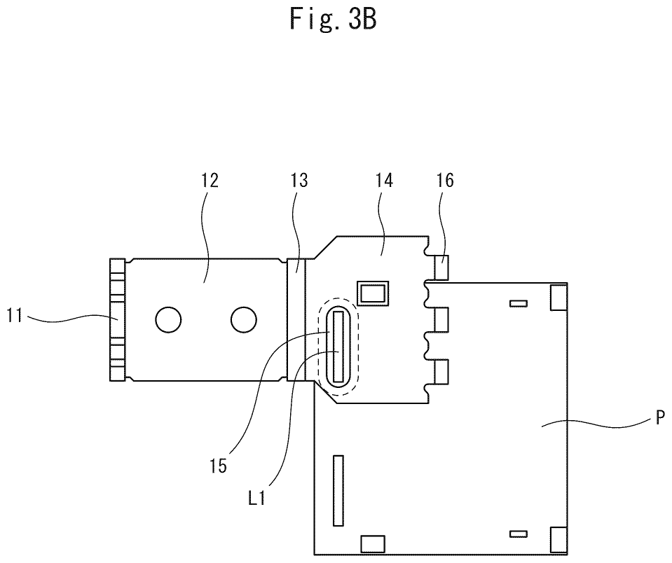

FIG. 3A is a perspective view of the short bar based on the first embodiment. In FIG. 3A, the engagement part 15 of the short bar S1 and the lead L1 of the part P are engaged with each other as described above. Such a configuration is also included in the scope of the present disclosure. Furthermore, FIG. 3B is a bottom view of FIG. 3A. As indicated by the dashed line in FIG. 3B, the region including the engagement part 15 and the lead L1 may be electrically connected by solder or solder flow. In such a case, the structure of the short bar S1 may be simple, and the short bar S1 can be produced at low cost.

Furthermore, it is preferable that the base part of the rising part 11 and the end part 16 of the second extension part 14 be soldered to a circuit pattern (not illustrated) formed on the back side of the printed circuit board C. The same is true for the leads L1, L2 of the part P.

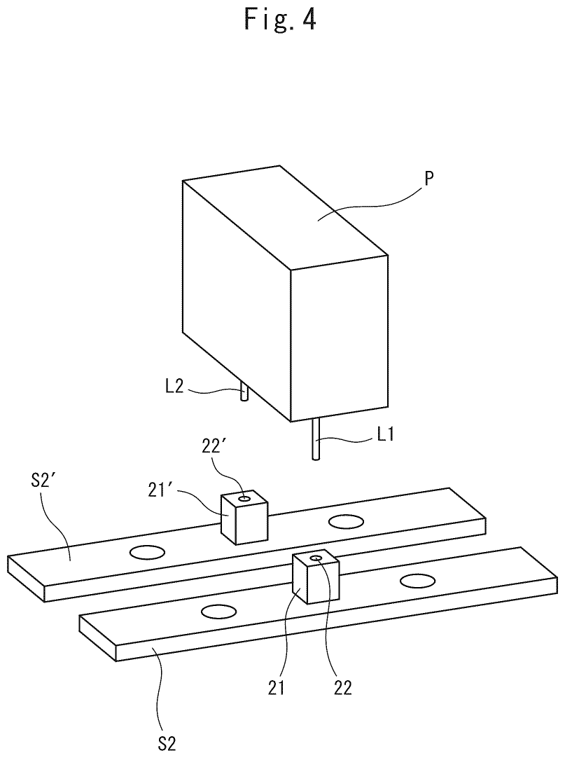

FIG. 4 is a perspective view of a short bar based on a second embodiment. In FIG. 4, two short bars S2, S2′ and a part P similar to that described above are shown. Sockets 21, 21′are provided on the short bars S2, S2′, respectively. Holes 22, 22′ which can be electrically connected to the short bars S2, S2′ are formed on the sockets 21, 21′. When the leads L1, L2 of the part P are engaged with the holes 22, 22′ of the sockets 21, 21′, respectively, the part P and the short bars S2, S2′ can be electrically connected to each other.

In this case, when it is necessary to replace the part P due to malfunction or the like, the part P can easily be removed by simply pulling out the leads L1, L2 of the part P from the sockets 21, 21′. Furthermore, a new part P can easily be attached by simply inserting the leads L1, L2 of the new part P into the holes 22, 22′ of the sockets 21, 21′.

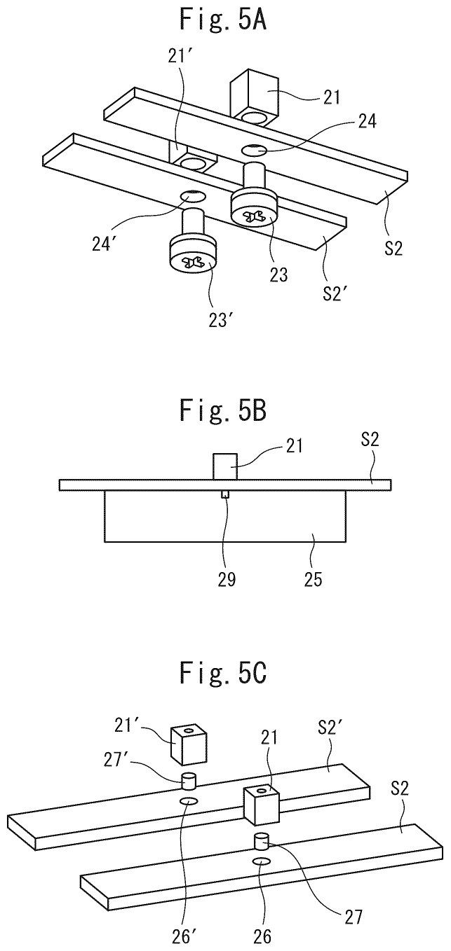

FIGS. 5A to 5C are views showing modification examples of the short bar shown in FIG. 4. In FIG. 5A, through holes 24, 24′ are formed on positions of the short bars S2, S2′ where the sockets 21, 21′ should be provided. Fasteners 23, 23′, such as screws or bolts, composed of a conductor are passed through the through holes 24, 24′ of the short bars S2, S2′ and screwed into the openings on the lower surfaces of the sockets 21, 21′. As a result, the sockets 21, 21′ can be affixed to the short bars S2, S2′, respectively.

In FIG. 5B, a conductor part 29 extending from the socket 21 penetrates the through hole of the short bar S2. The conductor part 29 and the short bar S2 are electrically connected to each other by solder flow 25.

In FIG. 5C, one ends of rods 27, 27′ composed of a conductor are press-fitted into the through holes 26, 26′ formed on the short bars S2, S2′. The other ends of the rods 27, 27′ are similarly press-fitted into holes on the bottom surfaces of the sockets 21, 21′. The configuration shown in FIG. 4 can be created by any of FIGS. 5A to 5C.

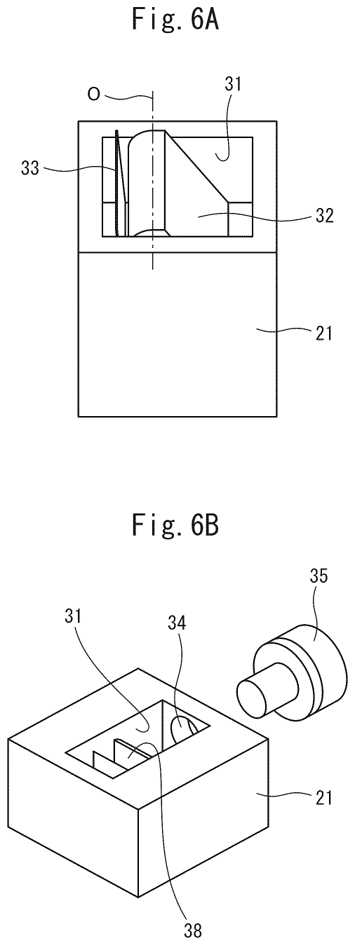

FIGS. 6A and 6B are views showing modification examples of the sockets shown in FIG. 4, etc. Though the socket 21 is shown in these drawings, the same applies to the socket 22. A hole 31 is formed on the upper surface of the socket 21 shown in FIG. 6A, and a plate part 32 which is rotatable about an axis O perpendicular to the insertion direction of the lead L1 is provided in the hole 31. The plate part 32 is biased by a leaf spring 33 in a direction which closes the hole 31.

Thus, when the lead L1 of the part P is inserted into the hole 31, the lead L1 presses the plate part 32 against the leaf spring 33. In the hole 31, the lead L1 is interposed between the inner wall part of the hole 31 and the plate part 32. To this end, the inner wall part of the hole 31 is preferably composed of a conductor.

In FIG. 6B, a through hole 34 is formed on the inner wall of the hole 31. When the lead L1 of the part P is inserted into the hole 31, a fastener 35 composed of a conductor is inserted into the through hole 34 to press and affix the lead L1 against an additional wall part 38 or the leaf spring in the hole 31.

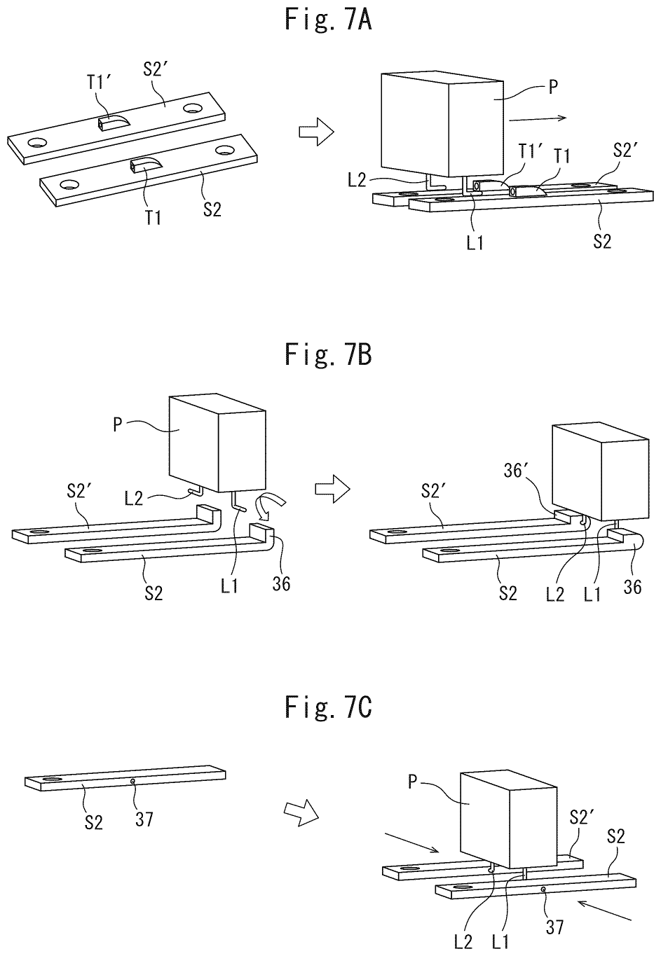

FIGS. 7A to 7C are views showing modification examples of the short bar shown in FIG. 4. On the left side of FIG. 7A, tunnels T1, T1′ are formed in the short bars S2, S2′, respectively. The tunnels T1, T1′ are raised portions in which a part of the lower surface of the short bars S2, S2′ is raised toward the upper surface, and at least one entrance is formed in each of the tunnels T1, T1′.

As shown on the right side of FIG. 7A, portions of the leads L1, L2 of the part P are curved so as to be parallel to the surfaces of the short bars S2, S2′. At this time, these portions of the leads L1, L2 are parallel to each other and extend in the same direction. The part P is then slid along the surfaces of the short bars S2, S2′, thereby inserting the leads L1, L2 into the interiors of the tunnels T1, T1′ from their entrances. Thereafter, the tunnels T1, T1′ are pressed so as to be crushed, thereby crimping the leads L1, L2 into the tunnels T1, T1′, respectively.

On the left side of FIG. 7B, portions of the leads L1, L2 of the part P are curved so as to be parallel to the surface of the short bars S2, S2′. At this time, these portions of the leads L1, L2 extend in opposite directions on the same straight line. End parts 36, 36′ of the short bars S2, S2′ are at least partially curved upward.

As shown on the right side of FIG. 7B, after the portions of the leads L1, L2 of the part P have abutted against the end parts 36, 36′ of the short bars S2, S2′, the end parts 36, 36′ are bent so as to fold back, thereby crimping the leads L1, L2 within the folded back portions of the end parts 36, 36′.

In FIG. 7C, a through hole 37 is formed in the thickness of the short bar S2. The same is true for the short bar S2′. Further, as shown in FIG. 7B, the tips of the curved leads L1, L2 are inserted into the through holes 37, 37′ of the short bars S2, S2′, respectively. Thereafter, the surfaces of the short bars S2, S2′ corresponding to the through holes 37, 37′ are pressed to crimp the leads L1, L2 into the through holes 37, 37′.

In this manner, in the modification examples shown in FIGS. 7A to 7C, it is advantageous in that the leads L1, L2 and the short bars S2, S2′ can be engaged to electrically connect the leads L1, L2 and the short bars S2, S2′, without requiring additional parts, such as fasteners or adhesives.

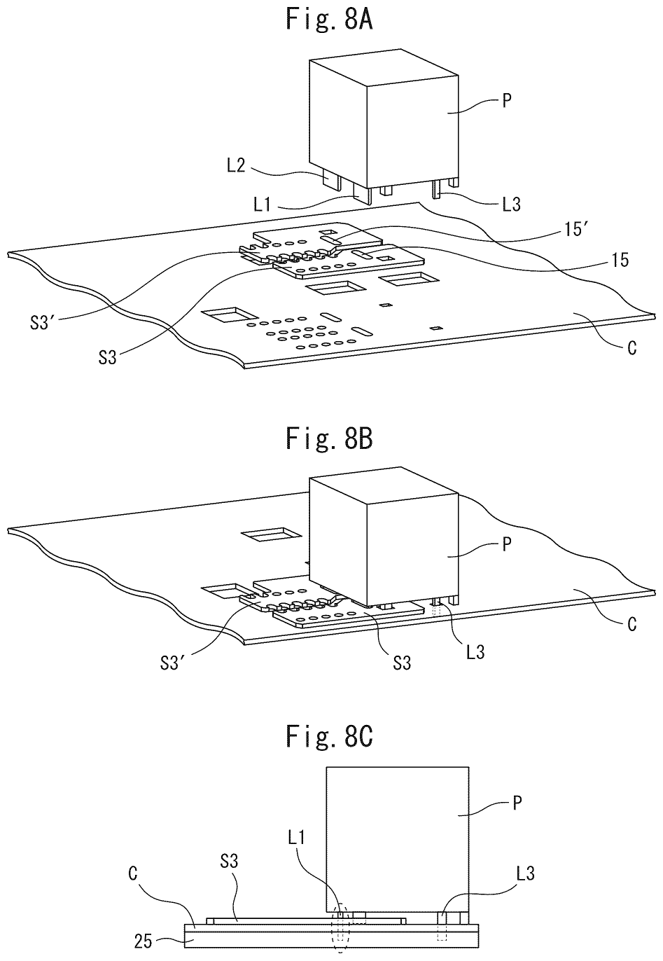

FIGS. 8A and 8B are perspective views showing a mounting structure of a third embodiment, and FIG. 8C is a side view of FIG. 8B. As shown in FIG. 8A, two short bars S3, S3′ are mounted on the surface of a printed circuit board C. These short bars S3, S3′ comprise engagement parts 15, 15′, for example, through holes, for engaging with the leads L1, L2 of the part P, respectively. The part P also comprises an additional lead L3 connected to the printed circuit board C in addition to the leads L1, L2.

As shown in FIG. 8B, the leads L1, L2 of the part P are engaged with the engagement parts 15, 15′ of the short bars S3, S3′, respectively. As a result, the leads L1, L2 penetrate the corresponding through holes formed on the printed circuit board C and extend to the back surface of the printed circuit board C.

Thereafter, as shown in FIG. 8C, the back side of the printed circuit board C is treated with solder or solder flow 25. As a result, in the region indicated by the dashed line in FIG. 8C, the leads L1, L2, the short bars S3, S3′, and the printed circuit board C are electrically connected in one treatment. Furthermore, in the same treatment, the lead L3 and the printed circuit board C are also electrically connected.

Thus, in the third embodiment, when treating the lead L3, which requires soldering, the leads L1, L2, the short bars S3, S3′, and the printed circuit board C can also be treated simultaneously, and the number of production steps can be reduced. It will be understood that in this treatment, the lead L2, the short bar S3′, and the printed circuit board C can also be treated simultaneously, and the number of production steps can be further reduced. Furthermore, in the third embodiment, it is not necessary for the short bars S3, S3′ to separately create an electrical connection part to the printed circuit board C and an electrical connection part to the part P. Thus, it is also possible to reduce the sizes of the short bars S3, S3′ and the printed circuit board C.

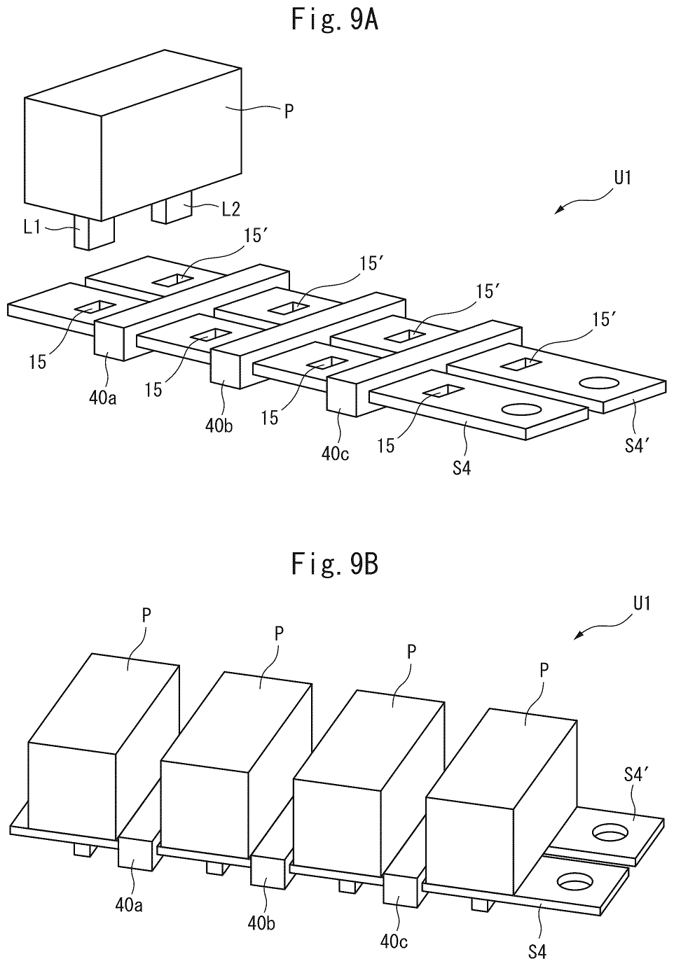

FIGS. 9A and 9B are perspective views of a unit according to a fourth embodiment. The unit U1 shown in these drawings comprises at least two short bars S4, S4′, the part P to be connected to the short bars S4, S4′, and at least one electrically insulation member 40a to 40c for affixing the short bars S4, S4′ to each other in a separated state.

Each of the short bars S4, S4′ comprises at least one engagement part 15. Thus, as shown in FIG. 9B, engagement with at least one part P is possible. The insulation members 40a to 40c are preferably composed of a hard resin.

The insulation members 40a to 40c can prevent the short bars S4, S4′ from shorting with each other. Furthermore, the presence of the insulation members 40a to 40c can strengthen the engagement between the short bars S4, S4′ and between the short bars S4, S4′ and the leads L1, L2. Thus, a unit U1 which is strong against external forces can be provided. Furthermore, the insulation members 40a to 40c also serve as positioning members for positioning the part P when it is mounted and when a servo amplifier (not illustrated) is attached.

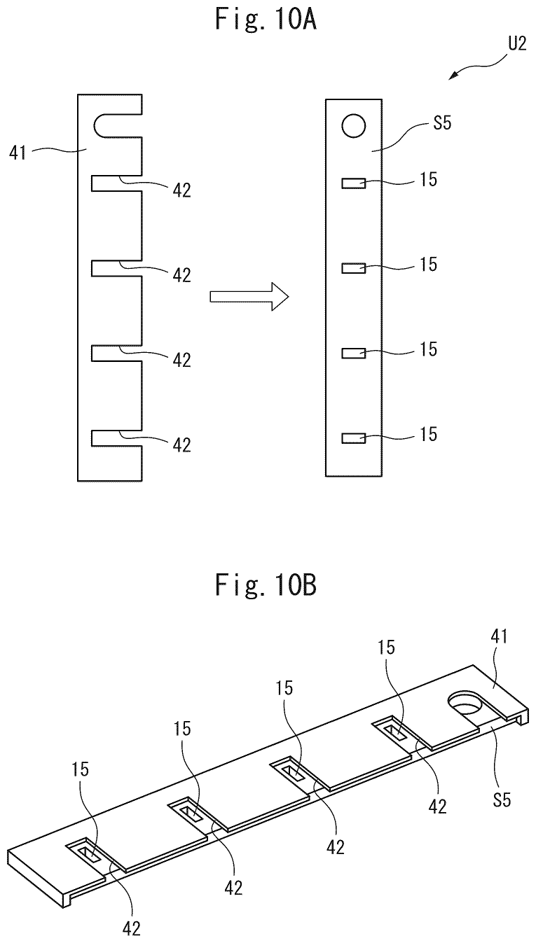

FIGS. 10A and 10B are views showing a unit based on a fifth embodiment. The unit U2 comprises a short bar S5 similar to that described above and an insulation coating 41 which at least partially covers the surface of the short bar S5. The insulation coating 41 is preferably composed of resin.

As can be understood from FIG. 10A, the short bar S5 comprises at least one engagement part 15. The insulation coating 41 comprises at least one notch 42 which generally corresponds to the at least one engagement part 15. The insulation coating 43 is then moved laterally to be attached to the short bar S5.

Strictly speaking, the insulation coating 41 insulates and covers the area of the short bar S5 excluding the at least one engagement part 15. The insulation coating 41 may be configured to cover only one side of the short bar S5, or may have a bag-like structure which covers both sides of the short bar S5. In this case, it can be attached by moving it laterally.

In the fifth embodiment, the insulation coating 41 serves as an electrical insulator between the short bar S5 and the part P (not illustrated in FIGS. 10A and 10B). Furthermore, by adjusting the thickness of the insulation coating 41, the insulation distance between the short bar S5 and the part P can be secured.

The insulation coating 41 fills the gap between the short bar S5 and the part P. Thus, even if the short bar S5 is used in a machine (not illustrated) which is subjected to excessive vibration during use, the strength of the machine against vibration can be increased.

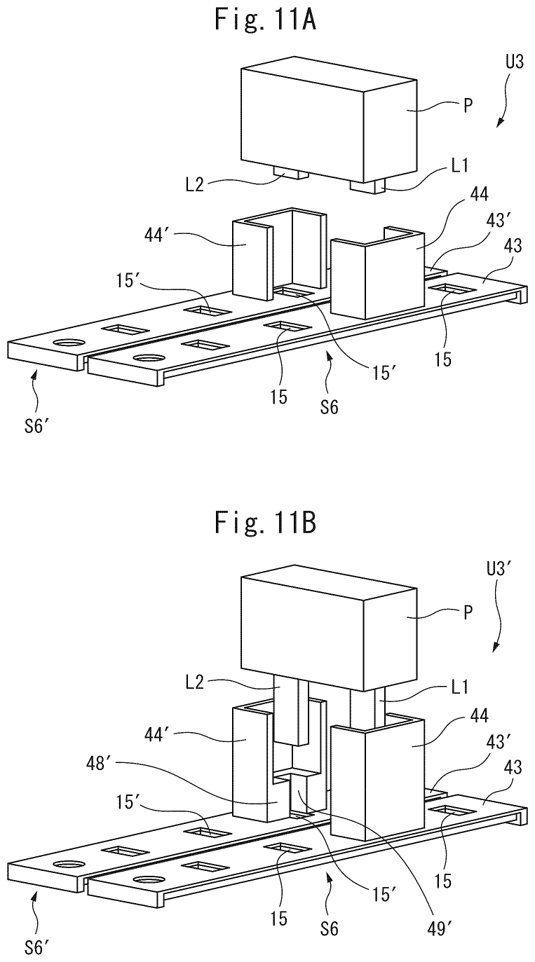

FIGS. 11A and 11B are perspective views of a unit according to a sixth embodiment. The unit U3 of the sixth embodiment primarily comprises at least one short bar S6, S6′ comprising an engagement part 15, 15′ (not illustrated in FIGS. 11A and 11B) similar to those described above, insulation coatings 43, 43′ similar to those described above, which at least partially cover the surfaces of the short bars S6, S6′, and a part P having a substantially rectangular parallelepiped shape.

Each of the insulation coatings 43, 43′ comprises a positioning part 44, 44′ for positioning the part P. The insulation coatings 43, 43′ and the positioning parts 44, 44′ are preferably formed integrally with each other. The insulation coatings 43, 43′ are attached to the short bars S6, S6′, respectively, in the same manner as described with reference to FIGS. 10A and 10B.

As can be understood from FIG. 11A, when the leads L1, L2 of the part P are engaged with the engagement parts 15, 15′ of the short bars S6, S6′, the part P is moved to the area formed by the two positioning parts 44, 44′. As described above, the positioning parts 44, 44′ are provided at positions corresponding to the engagement parts 15, 15′. Thus, by moving the part P so that the side parts of the part P slide along the wall parts of the positioning parts 44, 44′, the leads L1, L2 of the part P can be easily engaged with the engagement parts 15, 15′.

As can be understood from FIG. 11A, the positioning parts 44, 44′ are provided in the insulation coatings 43, 43′ at positions corresponding to the engagement parts 15, 15′. The positioning parts 44, 44′ include wall parts extending perpendicularly to the insulation coatings 43, 43′. The heights of the wall parts are preferably greater than half the height of the part P excluding the leads L1, L2.

In this manner, it is preferable that the positioning parts 44, 44′ have a shape corresponding to at least a part of the side of the part P. In this case, the positioning parts 44, 44′ can support at least a part of the side of the part P, and thus, the vibration resistance of the unit U3 can be improved.

When the part P having a substantially rectangular parallelepiped shape is viewed from above, the part P has four corners. Each of the positioning parts 44, 44′ shown in FIGS. 11A and 11B has a shape corresponding to two of the four corners. In an unillustrated embodiment, each of the positioning parts 44, 44′ may have a shape corresponding to one of the four corners. In this case, it is preferable that the corner of the part P corresponding to the positioning part 44 not be adjacent to the corner of the part P corresponding to the positioning part 44′.

Alternatively, each of the positioning parts 44, 44′ may have a shape corresponding to half of the side of the part P. Since the positioning parts 44, 44′ can cover the entire side of the part P in this case, the vibration resistance of the unit U3 can be improved and the entire side of the part P can be protected.

Furthermore, the case in which a single positioning part 44 has a wall part corresponding to the entire side of the part P, and the case in which a single positioning part 44 has wall parts corresponding to three or more of the four corners of the part P are included in the scope of the present disclosure.

In the unit U3′ shown in FIG. 11B, the part P comprises leads L1, L2 which are longer than those described above. The positioning parts 44, 44′ have spacers 48, 48′ inside the wall parts (the spacers 48 are not illustrated). The spacers 48, 48′ serve to adjust the lengths of the leads L1, L2 so that only a portion of the ends of the leads L1, L2 engage with the corresponding engagement parts 15, 15′. Thus, slits 49, 49′ through which the leads L1, L2 can pass are formed in the spacers 48, 48′ (the slit 49 is not illustrated). When the ends of the leads L1, L2 of the part P engage with the engagement parts 15, 15′, the bottom surface of the part P will be seated on the top ends of the spacers 48, 48′. In such a case, even if the leads L1, L2 of the part P are long, only a portion of the tips of the leads L1, L2 can be engaged with the engagement parts 15, 15′.

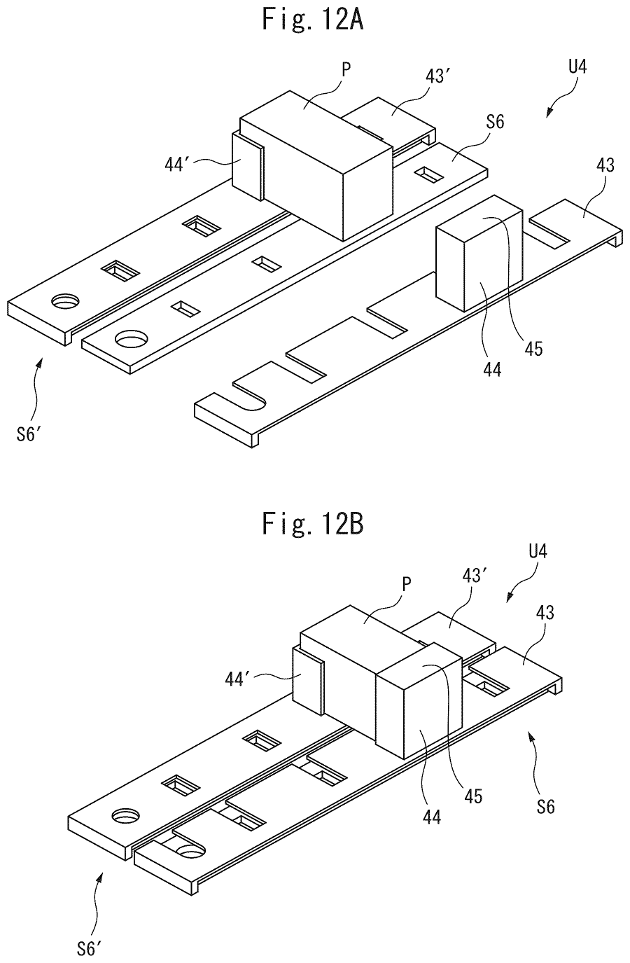

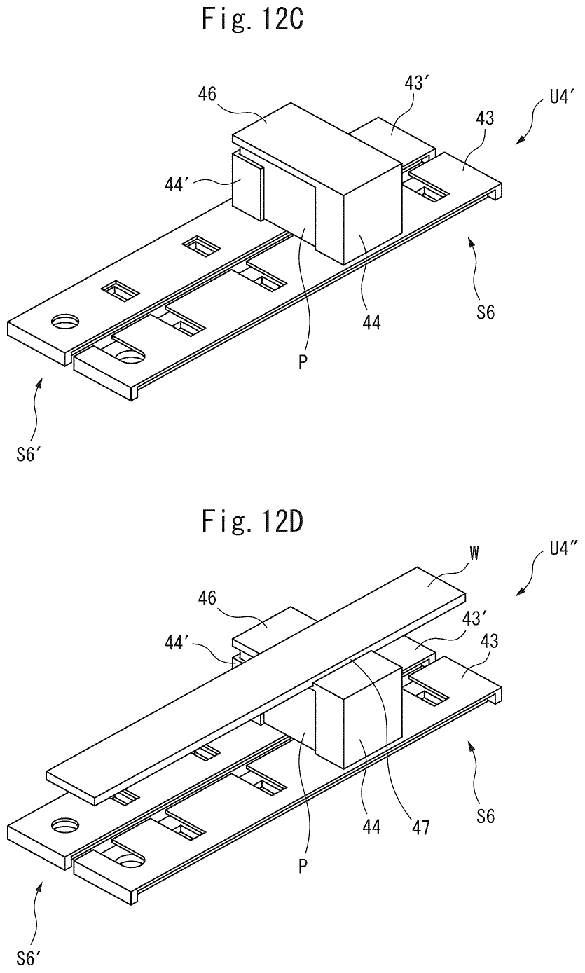

FIGS. 12A to 12D are perspective views of a unit according to a seventh embodiment. The unit U4 of the seventh embodiment primarily comprises at least one short bar S6, S6′ having engagement parts 15, 15′ (not illustrated in FIG. 12A, etc.) similar to those described above, insulation coatings 43, 43′ which at least partially cover the surfaces of the short bars S6, S6′, and a part P having a substantially rectangular parallelepiped shape.

Each of the insulation coatings 43, 43′ includes a positioning part 44, 44′ for positioning the part P. Furthermore, at least one of the insulation coatings 43 includes a closure part 45 that at least partially closes the upper surface of the part P. As shown in FIG. 12A, the closure part 45 is connected to the positioning part 44. Thus, it is preferable that the insulation coating 43, the positioning part 44, and the closure part 45 be integrally formed. Note that the height of the wall part of the positioning part 44 of the seventh embodiment is approximately equal to the height of the part P excluding the leads L1, L2.

As shown in FIG. 12B, the insulation coating 43 including the positioning part 44 and the closure part 45 is moved laterally to mount the insulation coating 43 on the short bar S6. Since the notch 42 is formed in the insulation coating 43 at a position corresponding to the engagement part 15, the insulation coating 43 does not interfere with the lead L1 of the part P when the insulation coating 43 is mounted. As a result, a part of the part P is disposed in the space defined by the positioning parts 44, 44′ and the closure part 45. In this case, the side and part of the top surface of the part P are affixed, whereby the vibration resistance can be further improved.

Furthermore, the insulation coating 43 of the unit U4′ of FIG. 12C comprises a positioning part 44 and a closure part 46. The closure part 46 has a size which covers the entire upper surface of the part P. It is preferable that the insulation coating 43, the positioning part 44, and the closure part 46 be integrally formed. Note that the insulation coating 43′ of FIG. 12C has the same configuration as the insulation coating 43′ shown in FIGS. 12A and 12B. It can be understood that the side and upper surfaces of the part P are affixed in FIG. 12C, which further improves vibration resistance.

In the unit U4″ shown in FIG. 12D, another part W is arranged on the closure part 46. In other words, the closure part 46 serves as an additional positioning part 47 for positioning the other part W. Thus, a groove, a protrusion, or the like corresponding to the other part W may be provided on the upper surface of the closure part 46. It will be understood that the additional positioning part 47 makes it easier to position the other part W. Note that the additional positioning part 47, such as a groove or a protrusion, may be formed on the outer surface of the positioning parts 44, 44′, so that the other part W is positioned on the outer surface of the positioning parts 44, 44′.

As an effect of at least one of the embodiments described above, the short bar and the lead of the lead part are directly engaged by the engagement part. Since the resistance value of the short bar is lower than that of the printed circuit board, heat generation of the short bar can be suppressed even when a large current is passed therethrough. Furthermore, there is no need to draw a large pattern on the printed circuit board, and the printed circuit board can be made smaller. Further, since there is no need to increase the thickness of the copper foil of the printed circuit board, production costs can be reduced.

Though the embodiments of the present disclosure have been described in detail, the present disclosure is not limited to the individual embodiments described above. Various additions, replacements, modifications, or partial deletions can be made to these embodiments within the scope of the spirit of the invention, or within the scope of the idea and intent of the present invention derived from the contents described in the claims and their equivalents. For example, the order of each operation and the order of each process of the embodiments described above are shown as examples, and are not limited to these. The same applies when numerical values or formulas are used in the description of the embodiments described above. Furthermore, appropriate combinations of some of the embodiments described above are included in the scope of the present disclosure.

In relation to the embodiments and modification examples described above, the following Addenda are further disclosed

### (Addendum 1)

A short bar for electrical connection to a lead part, comprising: an engagement part which is to be engaged with a lead of the lead part.

### (Addendum 2)

The short bar according to Addendum 1, wherein the engagement part is a socket for receiving the lead of the lead part.

### (Addendum 3)

The short bar according to Addendum 1, wherein the engagement part is a crimping portion for crimping the lead of the lead part.

### (Addendum 4)

The short bar according to Addendum 1 or 2, wherein the lead and the engagement part are electrically connected by solder or solder flow.

### (Addendum 5)

A mounting structure, comprising:
a printed circuit board, and
the short bar according to Addendum 1, which is mounted on the printed circuit board, wherein
the lead of the lead part which engages with the engagement part of the short bar passes over the short bar and penetrates a through hole of the printed circuit board.

### (Addendum 6)

The mounting structure according to Addendum 5, wherein the lead and the engagement part are electrically connected by solder or solder flow.

### (Addendum 7)

A mounting structure, comprising:
the short bar according to any of Addenda 1 to 4, and
a printed circuit board on which the short bar is mounted, wherein
the lead of the lead part penetrates a through hole of the printed circuit board and engages with the engagement part of the short bar.

### (Addendum 8)

A unit, comprising:
a plurality of the short bar according to any of Addenda 1 to 4, and
at least one insulation member for affixing the plurality of short bars in a separated state with each other.

### (Addendum 9)

A unit, comprising:
the short bar according to any of Addenda 1 to 4, and
an insulation coating for insulating and covering an area of the short bar excluding the engagement part.

### (Addendum 10)

The unit according to Addendum 9, wherein the insulation coating comprises a positioning part for positioning the lead part.

### (Addendum 11)

The unit according to Addendum 10, wherein the positioning part further comprises a closure part for at least partially closing an upper surface of the lead part.

### (Addendum 12)

The unit according to Addendum 10, wherein an additional positioning part is formed in the closure part.

### DESCRIPTION OF REFERENCE SIGNS

11, 13 rising part
12 first extension part
14 second extension part
15, 15′ engagement part
21, 21′ socket
22, 22′ hole
24, 24′ through hole
25 solder flow
27, 27′ rod
32 plate part
33 leaf spring
35 fastener
36, 36′ end part
37, 37′ through hole
38 additional wall part, leaf spring
40a to 40c insulation member
41 insulation coating
42 notch
43, 43′ insulation coating
44, 44′ positioning part
45,46 closure part
47 additional positioning part
48, 48′ spacer
49, 49′ slit
C printed circuit board
L1, L2 lead
P part
S1, S2, S2′, S3, S3′, S4, S4′, S5, S6, S6′ short bar
T1, T1′ tunnel
U1, U2, U3, U3′, U4, U4′ unit

What is claimed is:

1. A short bar for electrical connection to a lead part, comprising an engagement part which is to be engaged with a lead of the lead part.

2. The short bar according to claim 1, wherein the engagement part is a socket for receiving the lead of the lead part.

3. The short bar according to claim 1, wherein the engagement part is a crimping portion for crimping the lead of the lead part.

4. The short bar according to claim 1, wherein the lead and the engagement part are electrically connected by solder or solder flow.

5. A mounting structure, comprising:
a printed circuit board, and
the short bar according to claim 1, which is mounted on the printed circuit board, wherein
the lead of the lead part which engages with the engagement part of the short bar passes over the short bar and penetrates a through hole of the printed circuit board.

6. The mounting structure according to claim 5, wherein the lead and the engagement part are electrically connected by solder or solder flow.

7. A mounting structure, comprising:
the short bar according to claim 1, and
a printed circuit board on which the short bar is mounted, wherein
the lead of the lead part penetrates a through hole of the printed circuit board and engages with the engagement part of the short bar.

8. A unit, comprising:
a plurality of the short bar according to claim 1, and
at least one insulation member for affixing the plurality of short bars in a separated state with each other.

9. A unit, comprising:
the short bar according to claim 1, and
an insulation coating for insulating and covering an area of the short bar excluding the engagement part.

10. The unit according to claim 9, wherein the insulation coating comprises a positioning part for positioning the lead part.

11. The unit according to claim 10, wherein the positioning part further comprises a closure part for at least partially closing an upper surface of the lead part.

12. The unit according to claim 10, wherein an additional positioning part is formed in the closure part.
